(19) United States
(12) Patent Application Publication
(10) Pub. No.: US 2008/0142859 A1
(43) Pub. Date: Jun. 19, 2008

(54) Methods of forming ferroelectric media with patterned nano structures for data storage devices

(76) Inventors: Qing Ma, San Jose, CA (US); Li-Peng Wang, San Jose, CA (US)

Correspondence Address: INTEL CORPORATION;c/o INTELLEVATE, LLC, P.O. BOX 52050, MINNEAPOLIS, MN, 55402, US

(21) Appl. No.: 11/643,263

(22) Filed: Dec. 19, 2006

(51) Int. Cl. H01L 21/00; H01L 29/76

(52) U.S. Cl. 257/295; 438/3; 257/E21.663; 257/E29.272; 977/774

(57) ABSTRACT

Methods and associated structures of forming a microelectronic device are described. Those methods may forming a conductive layer on a substrate, patterning the conductive layer, forming at least one nanodot on the patterned conductive layer, and forming a thin film ferroelectric material on the at least one nanodot.

### BACK GROUND OF THE INVENTION

Ferroelectric thin films based on domain switching have been demonstrated to be promising media for probe-based data storage (PDS) devices. Both single and polycrystalline ferroelectric thin films have been investigated. For polycrystalline ferroelectric thin films, grain sizes lower than about 50 nm may be difficult to achieve. As a result, the bit size (and data density) may be limited for such films.

On the other hand, the processing temperature of crystalline ferroelectric thin films may exceed 550 degrees Celsius in some cases. This temperature may prove problematic when growing crystalline ferroelectric films on a CMOS wafer, which could have electronics of read channels, sense amplifiers, and control circuitry that may be damaged at such a temperature. Additionally, many of the techniques used to form high-quality crystalline ferroelectric films, such as pulsed laser deposition (PLD), molecular beam epitaxy (MBE), metal oxide chemical vapor deposition (MOCVD), may be difficult for high-volume manufacturing.

### BRIEF DESCRIPTION OF THE DRAWINGS

While the specification concludes with claims particularly pointing out and distinctly claiming that which is regarded as the present invention, the advantages of this invention can be more readily ascertained from the following description of the invention when read in conjunction with the accompanying drawings in which:

FIGS. 1a-1g represent structures according to an embodiment of the present invention.

FIG. 2 represents a system according to an embodiment of the present invention.

### DETAILED DESCRIPTION OF THE PRESENT INVENTION

In the following detailed description, reference is made to the accompanying drawings that show, by way of illustration, specific embodiments in which the invention may be practiced. These embodiments are described in sufficient detail to enable those skilled in the art to practice the invention. It is to be understood that the various embodiments of the invention, although different, are not necessarily mutually exclusive. For example, a particular feature, structure, or characteristic described herein, in connection with one embodiment, may be implemented within other embodiments without departing from the spirit and scope of the invention. In addition, it is to be understood that the location or arrangement of individual elements within each disclosed embodiment may be modified without departing from the spirit and scope of the invention. The following detailed description is, therefore, not to be taken in a limiting sense, and the scope of the present invention is defined only by the appended claims, appropriately interpreted, along with the full range of equivalents to which the claims are entitled. In the drawings, like numerals refer to the same or similar functionality throughout the several views.

Methods and associated structures of forming microelectronic structures are described. Those methods may comprise forming a conductive layer on a substrate, patterning the conductive layer, forming at least one nanodot on the patterned conductive layer, and forming a thin film ferroelectric material on the at least one nanodot. Methods of the present invention may decrease the bit size of ferroelectric devices below 25 nm.

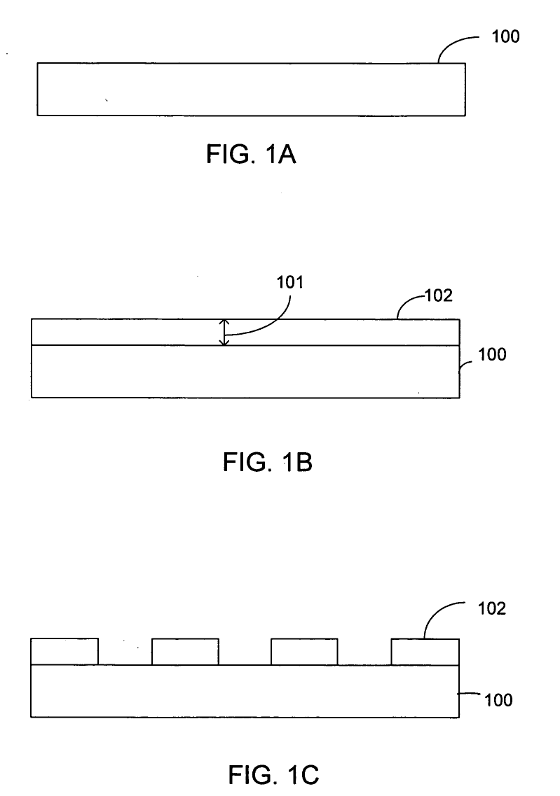

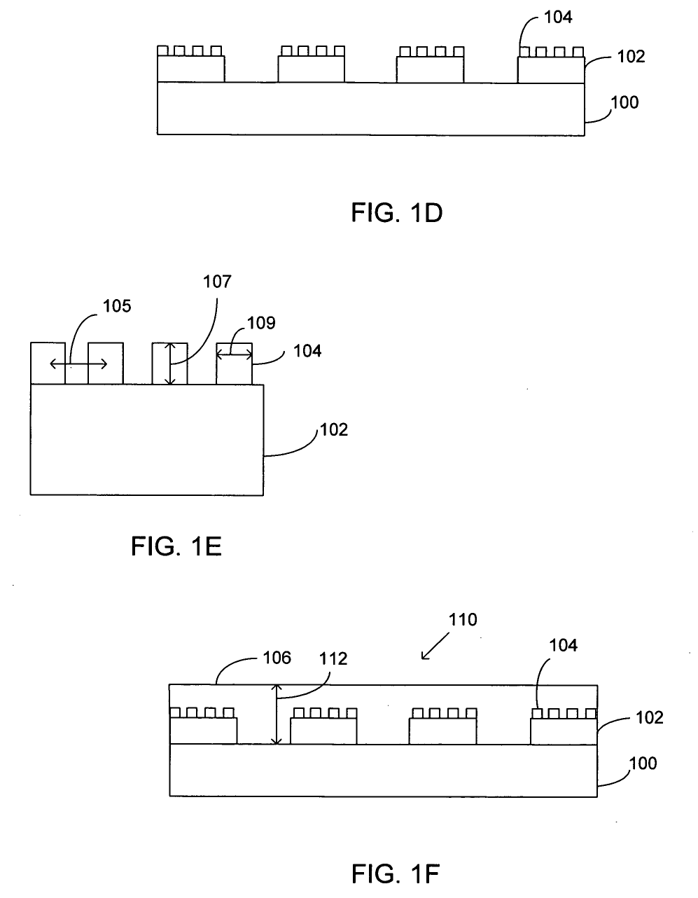

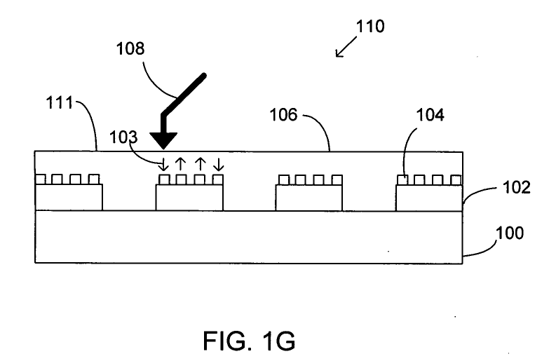

FIGS. 1a-1g illustrate embodiments of methods of forming thin film ferroelectric structures, such as may be used in data storage, such as in PDS devices for example. FIG. 1a illustrates a cross-section of a substrate 100. The substrate 100 may comprise a wafer in some embodiments, and may comprise circuitry for PDS functions, including but not limited to reading and writing functions, for example. The substrate 100 may comprise silicon in some cases, or any other suitable type of wafer material, depending upon the particular application.

In one embodiment, the substrate 100 may comprise at least one of writing nano-pulse circuitry and reading amplifier circuitry, and the like. In one embodiment, the substrate 100 may comprise a CMOS microelectronic wafer, which may comprise a diameter suitable for the particular application, such as a diameter of about 8 inches or greater, in some cases.

A conductive layer 102, may be formed on the substrate 100 (FIG. 1b). The conductive layer 102 may comprise any type of conductive material, and in some cases may comprise a material that may function as an electrode, such as a copper material, for example. In one embodiment, the conductive layer 102 may comprise a thickness 101 of about 1 micron or below. The conductive layer 102 may be patterned (FIG. 1c). The shape of the patterned conductive material 102 may depend upon the particular application, but may be patterned according to electrode patterning requirements for various PDS circuits, in some embodiments.

At least one nanodot 104 may be formed on the patterned conductive layer 102 (FIG. 1d). In one embodiment, the at least one nanodot 104 may be formed utilizing self-assembly techniques, such as, for example, by using spin-on co-polymer materials. The self assembly technique may result in a more regular array of nanodots than various other non-self assembly techniques, such as deposition techniques, for example.

In one embodiment, two different polymers (co-polymers) may be mixed together, spun on the wafer, and annealed. The two polymers may then separate from each other and may form regular patterns of regular structures at nano-scale on the patterned conductive material 102. A solvent may be applied to the wafer that can dissolve one of the polymers and not the other. In one embodiment, an etch process may be utilized to form nanodots 104 on the patterned conductive material 102. The polymer may then be stripped.

In one embodiment, the at least one nanodot 104 may comprise a thickness 107 of about 5 nm to about 10 nm, and a pitch 105 as measured from about the middle of adjacent nanodots 104 of less than about 20 nm (FIG. 1e). In another embodiment, a diameter 109 of the at least one nanodot 104 may be less than about 20 nm, and a thickness 107 of the dots may comprise about 30 nm and below. The exact dimensions and geometries of the at least one nanodot 104 may vary depending upon the particular application, and can comprise any shape suitable for the application.

In one embodiment, the at least one nanodot 104 formed by deposition techniques may comprise about 1-2 nm in thickness 107. In one embodiment, subsequent to its formation, the material used to form the at least one nanodot 104 may be heated by utilizing a rapid thermal process (RTP). The time of the heating will depend upon the application, but may comprise less than about 10 seconds in some embodiments. The material used to form the at least one nanodot 104 may then bead up with the application of the heating process, and may thus form the at least on nanodot 104. Nanodots formed in this manner may comprise a more random arrangement, but may be cheaper to process than non-deposition methods of formation.

A thin film ferroelectric material 106 may be formed on the at least one nanodot 104 (FIG. 1f). In one embodiment, the ferroelectric material 106 may comprise lead zirconium titanate (PZT), Barium titanate oxide (BTO, Strontium bismuth tantalate (SBT), Lanthanum strontium cobalt oxide (LSCO) and Bismuth iron oxide (BFO). The thin film ferroelectric material 106 may be formed by sputtering, metal oxide chemical vapor deposition (MOCVD), or any suitable deposition/formation method, depending upon the application. In one embodiment, a thickness 112 of the thin film ferroelectric material 106 may be about 20 nm to about 50 nm. In one embodiment, the thin film ferroelectric material 106 may be formed at a temperature of less than about 450 degrees Celsius, and in some cases, less than about 300 degrees Celsius. In one embodiment, the at least one nanodot 104, the conductive material 102 and the thin film ferroelectric material 106 may comprise a thin film ferroelectric structure 110.

At least one probe 108, such as but not limited to an atomic force probe (AFP), as is known in the art, may be placed in contact/proximity with the thin film ferroelectric material 106 (FIG. 1g). The thin film ferroelectric material 106 may comprise at least one domain 103. The at least one domain 103 may be oriented normal to the surface of the thin film ferroelectric material 106, in some cases. Each individual domain 103 of the thin film ferroelectric material 106 may hold 1 bit of information in some embodiments.

The at least one domain 103 can be induced to align with a positive or negative electric field that may be applied by the at least one probe 108, and can be made to point up or down, according to the polarity of the probe electric field. In one embodiment, the at least one nanodot 104 may act to define a smaller domain 103 than domains that might be present without the use of the at least one nanodot 104. For example, polycrystalline thin films used without nanodots may comprise domains of about 50 nm and above in size, in some cases.

In one embodiment, the at least one nanodot 104 may act as a sharp nanoprobe tip, so that an electric field applied by the at least one probe 108 is substantially focused within the confines of the at least one nanodot 104. In one embodiment, the at least one nanodot 104 may comprise a thickness of about 2 to about 4 nm. In another embodiment, a pitch of the at least one nanodot 104 may comprise about 6 nm or less. Because the electric field that may be applied by the at least one probe 108 may be substantially focused within the at least one nanodot 104, the thin film ferroelectric structure 110 comprises the capability to write/read/program to a domain that is substantially smaller (in some cases 5 nm or less) than without the nanodots of the present invention.

In one embodiment, a read operation of the information stored in the domain 103 (bit) of the thin film ferroelectric material 100 may comprise contacting and/or passing the at least one probe 108 over the surface 111 of the thin film ferroelectric material 106 and applying a voltage between the at least one probe 108 and the at least one nanodot 104. In one embodiment, the at least one probe 108 is capable of sensing a change in polarization of the domain 103 when it is over or near the domain 103 (that is substantially located within the nanodot region). When the at least one probe 108 senses the change in polarization, the at least one probe 108 (which may be coupled to appropriate electronic equipment not shown in the figure), may register the data bit as a 1 or a 0, as the case may be.

In some cases, the domain size of a ferroelectric material can be a critical factor in determining the storage capacity of storage devices utilizing ferroelectric material, such as but not limited to PDS devices. By utilizing the nanodots of the present invention, the storage capacity of ferroelectric storage devices can be increased by orders of magnitude. Therefore, integration of thin film ferroelectric material into PDS systems extends the scaling of the bit size below about 10 nm, and thus increases the storage capacity of various memory applications, such as in minidisks, PDS related applications and various microelectromechanical (MEMS) related devices.

The thin film ferroelectric material 100 can be deposited as a storage media at reduced processing temperature that may be compatible with materials comprising CMOS wafers, for example. The nanodot structures of the present invention assist in defining and/or stabilizing the switchable domains of the thin film ferroelectric material 100 without the requirement of high-quality, high-processing-temperature crystal ferroelectric films.

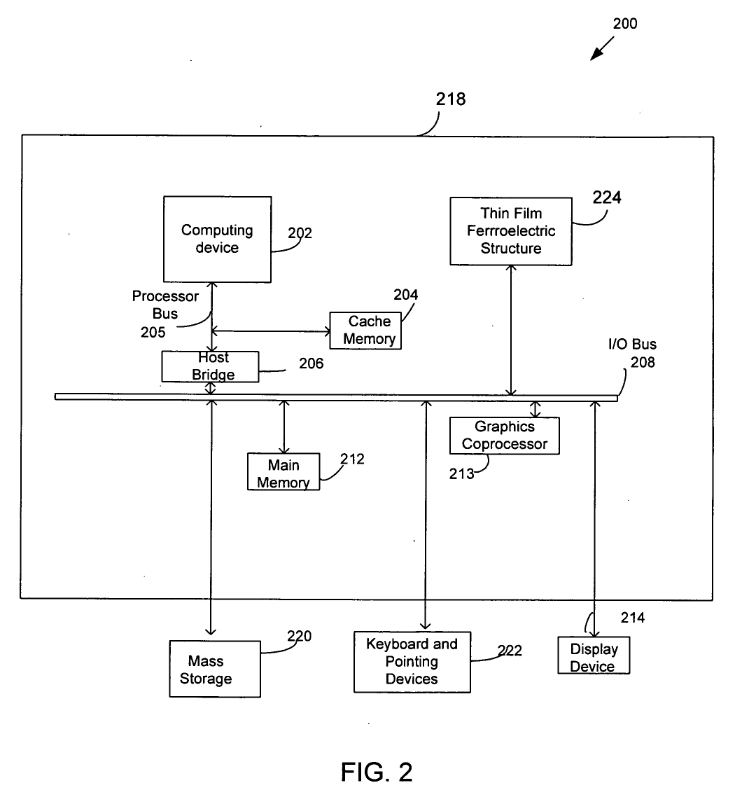

FIG. 2 is a diagram illustrating an exemplary system 200 capable of being operated with methods for fabricating a microelectronic structure, such as the thin film ferroelectric structure of FIG. 1f, for example. It will be understood that the present embodiment is but one of many possible systems in which the thin film ferroelectric structures of the present invention may be used.

In the system 200, the thin film ferroelectric structure 224 may be communicatively coupled to a printed circuit board (PCB) 218 by way of an I/O bus 208. The communicative coupling of the thin film ferroelectric structure 224 may be established by physical means, such as through the use of a package and/or a socket connection to mount the thin film ferroelectric structure 224 to the PCB 218 (for example by the use of a chip package, interposer and/or a land grid array socket). The thin film ferroelectric structure 224 may also be communicatively coupled to the PCB 218 through various wireless means (for example, without the use of a physical connection to the PCB), as are well known in the art.

The system 200 may include a computing device 202, such as a processor, and a cache memory 204 communicatively coupled to each other through a processor bus 205. In one embodiment, the computing device 202 may comprise at least one thin film ferroelectric structure. The processor bus 205 and the I/O bus 208 may be bridged by a host bridge 206. Communicatively coupled to the I/O bus 208 and also to the thin film ferroelectric structure 224 may be a main memory 212. Examples of the main memory 212 may include, but are not limited to, static random access memory (SRAM) and/or dynamic random access memory (DRAM), and/or some other state preserving mediums. In one embodiment, the main memory 212 may comprise at least one thin film ferroelectric structure. The system 200 may also include a graphics coprocessor 213, however incorporation of the graphics coprocessor 213 into the system 200 is not necessary to the operation of the system 200. Coupled to the I/O bus 208 may also, for example, be a display device 214, a mass storage device 220, and keyboard and pointing devices 222. In one embodiment, the mass storage device 220 may comprise at least one thin film ferroelectric structure.

These elements perform their conventional functions well known in the art. In particular, mass storage 220 may be used to provide long-term storage for the executable instructions for a method for forming and/or utilizing thin film ferroelectric structures in accordance with embodiments of the present invention, whereas main memory 212 may be used to store on a shorter term basis the executable instructions of a method for forming and/or utilizing thin film ferroelectric structures in accordance with embodiments of the present invention during execution by computing device 202. In addition, the instructions may be stored, or otherwise associated with, machine accessible mediums communicatively coupled with the system, such as compact disk read only memories (CD-ROMs), digital versatile disks (DVDs), and floppy disks, carrier waves, and/or other propagated signals, for example. In one embodiment, main memory 212 may supply the computing device 202 (which may be a processor, for example) with the executable instructions for execution.

Although the foregoing description has specified certain steps and materials that may be used in the method of the present invention, those skilled in the art will appreciate that many modifications and substitutions may be made. Accordingly, it is intended that all such modifications, alterations, substitutions and additions be considered to fall within the spirit and scope of the invention as defined by the appended claims. In addition, it is appreciated that certain aspects of microelectronic devices, such as memory related structures, are well known in the art. Therefore, it is appreciated that the Figures provided herein illustrate only portions of an exemplary microelectronic device that pertains to the practice of the present invention. Thus the present invention is not limited to the structures described herein.

What is claimed is:

1. A method comprising:
forming a conductive layer on a substrate;
patterning the conductive layer;
forming at least one nanodot on the patterned conductive layer; and
forming a thin film ferroelectric material on the at least one nanodot.

2. The method of claim 1 wherein thin film ferroelectric material comprises at least one of lead zirconium titanate, barium titanate oxide, strontium bismuth tantalate, lanthanum strontium cobalt oxide and bismuth iron oxide.

3. The method of claim 1 further comprising coupling at least one probe to the thin film ferroelectric material that is capable of supplying current to the thin film ferroelectric material, wherein a domain of the thin film ferroelectric material is switched.

4. The method of claim 3 wherein switching the domain of the thin film ferroelectric material comprises storing data in the thin film ferroelectric material.

5. The method of claim 3 wherein the at least one probe is capable of at least one of writing and reading data to and from the thin film ferroelectric material.

6. The method of claim 1 wherein forming the at least one nanodot comprises forming the at least one nanodot by a self assembly technique.

7. The method of claim 3 further comprising wherein a pitch between adjacent nanodots comprises less than about 20 nm.

8. A structure comprising:
a patterned conductive layer disposed on a substrate;
at least one nanodot disposed on the patterned conductive layer; and
a thin film ferroelectric material disposed on the patterned conductive layer.

9. The structure of claim 8 wherein the thin film ferroelectric material comprises at least one of lead zirconium titanate, barium titanate oxide, strontium bismuth tantalate, lanthanum strontium cobalt oxide and bismuth iron oxide.

10. The structure of claim 8 wherein the structure comprises a portion of at least one of a PDS circuit and a MEMS circuit.

11. The structure of claim 8 further comprising at least one probe proximate to the thin film ferroelectric material that is capable of switching a domain of the thin film ferroelectric material.

12. The structure of claim 8 wherein a pitch between individual ones of the at least one nanodot comprises below about 20 nm.

13. The structure of claim 11 wherein the at least one probe is capable of at least one of writing and reading data to and from the domain of the thin film ferroelectric material.

14. The structure of claim 8 wherein the substrate comprises at least one of capabilities for writing nanosecond pulse and reading amplifier.

15. The structure of claim 8 wherein the substrate comprises a CMOS wafer.
